(19) United States
(12) Patent Application Publication
(10) Pub. No.: US 2009/0091394 A1
(43) Pub. Date: Apr. 9, 2009

(54) DEVICE TO GENERATE A MODULATED ELECTRICAL RADIO-FREQUENCY SIGNAL FOR A MAGNETIC RESONANCE APPLICATION

(76) Inventor: Axel Friedrich, Nuernberg (DE)

Correspondence Address: SCHIFF HARDIN, LLP;PATENT DEPARTMENT, 6600 SEARS TOWER, CHICAGO, IL, 60606-6473, US

(21) Appl. No.: 12/247,377

(22) Filed: Oct. 8, 2008

(30) Foreign Application Priority Data
Oct. 8, 2007 (DE) 10 2007 048 167.7

(51) Int. Cl. H03C 1/02

(52) U.S. Cl. 330/297

(57) ABSTRACT

A device for generation a modulated electrical radio-frequency signal for a magnetic resonance application has a phase modulator that generates a phase-modulated radio-frequency base signal, an amplitude modulator that generates an amplitude-modulated supply voltage, and a non-linear transmission output stage that, to supply the radio-frequency base signal, is connected via a signal input with the phase modulator and, to feed in the supply voltage, is connected via a supply voltage input with the amplitude modulator. The amplitude modulator includes at least two switching power supplies connected in parallel and clocked phase-offset relative to one another.

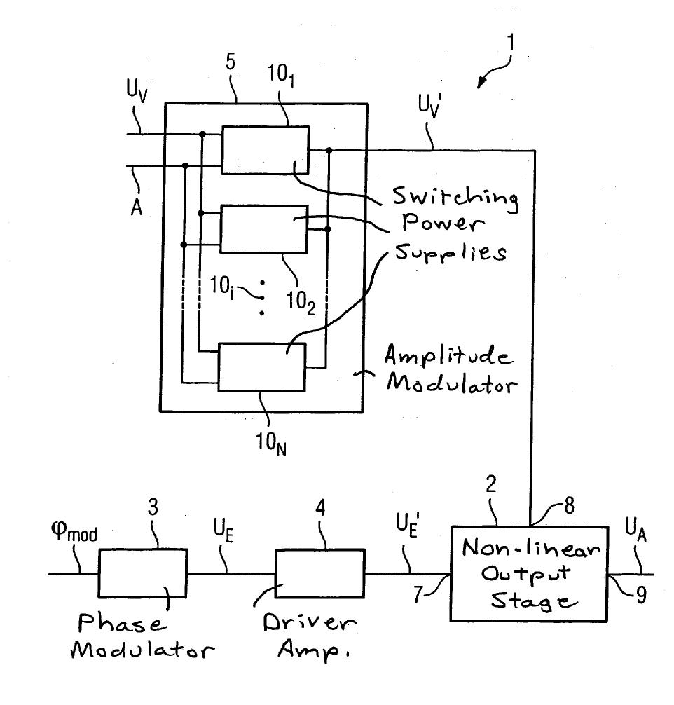

### BACKGROUND OF THE INVENTION

1. Field of the Invention

The present invention concerns a device of the type suitable for generating a modulated electrical radio-frequency signal for use in a magnetic resonance apparatus.

2. Description of the Prior Art

In data acquisitions that are based on magnetic resonance effects of atomic nuclei, in particular in (medical and non-medical) magnetic resonance tomography including imaging and magnetic resonance spectroscopy, a modulated, electrical radio-frequency signal is used to generate an electromagnetic radio-frequency field with which specific atomic nuclei of an examination subject are excited. An amplitude-modulated and phase-modulated alternating electrical voltage with frequencies on the order of 10-400 MHz is often used as a radio-frequency signal. This voltage must be provided with comparably high power. For example, in modern magnetic resonance tomography a radio-frequency signal with a peak power of 40 kW and an average power of approximately 2 kW is required. The frequency of the amplitude modulation is typically on the order of approximately 10 kHz. Devices to generate this radio-frequency signal are also designated as magnetic resonance (MR) transmitters.

A conventional MR transmitter has a modulator that generates an amplitude- and phase-modulated basic signal in the low or sub-watt range. This basic signal is initially preamplified in a driver amplifier, typically a power of 100 W, for instance. The preamplified signal is then amplified in a transmission output stage to the desired end power, for example to 30 kW.

A linear output stage, i.e. an electronic amplifier of Class A or AB, is conventionally used as a transmission output stage. Such a linear output stage is disadvantageously characterized by a high power loss that results as waste heat and must be dissipated by elaborate cooling devices. The operation of such an MR transmitter correspondingly requires a high mains power. A sufficiently powerful linear output stage is additionally relatively large and expensive.

### SUMMARY OF THE INVENTION

An object of the invention is to provide a device that is improved with regard to the above characteristics in order to generate an electrical radio-frequency signal for MR applications.

According to the invention, this object is achieved by a device having a phase modulator that generates a phase-modulated radio-frequency signal as well as a separate amplitude modulator to generate an amplitude-modulated supply voltage. The device furthermore has a non-linear transmission output stage. The transmission output stage is connected with the phase modulator via a signal input to supply the radio-frequency base signal (indirectly or directly). By contrast, the amplitude modulator is connected with a power supply input of the transmission output stage to feed in the supply voltage. The amplitude modulator is formed by at least two clocked, switching power supplies connected in parallel that are operated phase-offset relative to one another.

The invention is based on the recognition that the efficiency of the MR transmission can be significantly increased by using a non-linear transmission output stage instead of a linear transmission output stage. An electronic power amplifier of Classes B, C, D, R or F is in particular designated as a non-linear transmission output stage. According to the conventional assumptions described above, the linear output stage in a conventional transmitter design cannot be replaced by a non-linear output stage without further measures, especially as the amplitude modulation of the supplied radio-frequency base signal would be wholly or partially lost in this case. According to the conventional assumptions, however, the use of the non-linear transmission output stage is possible because—deviating from the conventional transmitter design—the amplitude modulation is not already impressed on the base signal, but rather on the supply voltage of the transmission output stage.

The invention furthermore proceeds from the recognition that the amplitude modulation can in principle be applied to the supply voltage either by a high-power linear regulator or by a switching power supply, but both variants have fundamental, specific disadvantages. The use of a linear regulator to generate the amplitude-modulated supply voltage would at least partially negate the advantages intended with the invention, especially as such a linear regulator (similar to the conventionally used linear output stage) would be high-loss, large and comparably expensive. A very low power loss and a correspondingly lower mains power would result given use of a conventional switching power supply. A sufficiently powerful switching power supply would also normally be smaller and cheaper than a corresponding linear regulator. Due to the switching processes in the power supply, however, a radio-frequency voltage fluctuation would be modulated to the supply voltage that would overlap the intended amplitude modulation of said supply voltage. Given the use of typical switching power supplies, this ripple voltage would lie in a frequency range similar to that of the amplitude modulation to be applied. The ripple voltage would therefore severely disrupt the radio-frequency signal to be generated by the transmission output stage and lead, for example, to image artifacts and other quality losses of the image data to be generated in the MR imaging.

Within this dichotomy, a synthesis is found according to the invention by the use of multiple switching power supplies connected in parallel and clocked with phase offset relative to one another. Namely, the characteristic frequencies of the ripple voltage multiply with the number of switching power supplies used due to the phase-offset clocking. The phase voltage can thus be sufficiently spectrally separated from the amplitude modulation of the supply voltage, such that the ripple voltage cannot appreciably influence the measurement-relevant nuclear magnetic excitation and/or the image, or at least can be eliminated with simple frequency filters without impairing the amplitude modulation.

The use of switching power supplies to generate the amplitude-modulated supply voltage simultaneously enables a compact, cost-effective and particularly effective amplitude modulator to be achieved that is suitable to supply voltage to the non-linear transmission output stage.

In a preferred embodiment of the device, the switching power supplies are cyclically phase-offset from one another by the same switching phase differences. The switching power supplies are thus respectively phase-offset by a switching phase difference of 2·π/N, wherein N stands the number of switching power supplies. The switching processes of the switching power supplies are hereby distributed particularly uniformly over time, so low-frequency portions of the ripple voltage generated by these switching processes are particularly effectively suppressed.

In a simple and cost-effective design, the switching power supplies are fashioned as what are known as buck converters (also: called step-down converters).

A driver amplifier is appropriately also interconnected between the phase modulator and the transmission output stage, analogous to conventional transmitter designs.

### BRIEF DESCRIPTION OF THE DRAWING

The single FIGURE shows an exemplary embodiment of a device according to the invention to generate a modulated electrical radio-frequency signal U_{A} for a magnetic resonance application (subsequently designated as an MR transmitter 1).

### DESCRIPTION OF THE PREFERRED EMBODIMENTS

The shown MR transmitter 1 has a non-linear transmission output stage 2, a phase modulator 3, a driver amplifier 4 and an amplitude modulator 5.

The transmission output stage 2 is an electronic amplifier of Classes B, C, D, E or F. The transmission output stage 2 has a signal input 7 for an input signal to be amplified, to which input 7 the phase modulator 3 is indirectly connected via the driver amplifier 4. The transmission output stage 2 furthermore has a voltage supply input 8 to which the amplitude modulator 5 is connected. The transmission output stage 2 finally also has a signal output 9 to output the radio-frequency signal U_{S}.

In operation of the MR transmitter 1, the phase modulator 3 generates a radio-frequency (RF) base signal U_{E} which is an alternating electrical voltage in the sub-watt range with a carrier frequency of, for example, 120 MHz. The RF base signal U_{E} is phase-modulated by the phase modulator 3 according to the requirement of a supplied desired phase value φ_{mod} that varies in a time-dependent manner:

U_{E}(t)=U_{E0}·sin(2πf₀t+φ_{mod}(t)),

wherein U_{E0} stands for a constant voltage amplitude (for example of approximately 5V), f₀ stands for the carrier frequency and t stands for the time. The RF base signal is linearly preamplified in the driver amplifier 4 to a power of approximately 100 W and is provided as a preamplified RF base signal U_{E}′ to the signal input 7 of the transmission output stage 2.

A constant supply voltage U_{V} of, for example, 200V is supplied by a rectifier (also: power supply unit; not shown in detail) to the amplitude modulator 5 connected in the voltage supply path of the transmission output stage 2. A temporally varying desired amplitude value A=A(t) is additionally supplied to the amplitude modulator 5, according to the requirements of which the amplitude modulator 5 derives an amplitude-modulated supply voltage U_{V}′ from the supplied constant supply voltage U_{V}.

In a characteristic application for magnetic resonance tomography, the amplitude-modulated supply voltage U_{V}′ is a temporally variable voltage of the form

U_{V}′(t)=|160V·sin(2πft)/(2πft)|,

wherein t again stands for time and f stands for a typical frequency of the amplitude modulation. The frequency f is typically on the order of 10 kHz.

The amplitude-modulated supply voltage U_{V}′ is provided to the supply voltage input 8 of the transmission output stage 2. The transmission output stage 2 generates the phase-modulated and amplitude-modulated output signal U_{A} from the phase-amplified RF base signal U_{E}′ and the phase-modulated supply voltage U_{V}′.

The amplitude modulator 5 comprises a number N (N=2, 3, . . . ; for example N=10) of identically designed switching power supplies 10ᵢ (i=1, 2, . . . , N). The switching power supplies 10ᵢ are connected in parallel with one another in the power supply path. The desired amplitude value A is additionally supplied to each switching power supply 10ᵢ.

Each of the switching power supplies 10ᵢ is clocked with the same switching frequency, wherein the individual switching power supplies 10ᵢ are clocked phase-offset by an equidistant Δφ. This means that, relative to the cyclically adjacent switching power supplies, each switching power supply 10ᵢ switches with a phase offset Δφ of Δφ=2π/N relative to the clock cycle of the switching power supplies 10ᵢ. For each switching power supply 10ᵢ, an associated switching phase φᵢ thus results at

φᵢ=2πi/N with i=1, 2, . . . , N.

Through the phase-offset clocking of each switching power supply 10ᵢ, as a consequence of the switching processes of all switching power supplies 10ᵢ a ripple voltage is modulated to the supply voltage U_{V}′, the frequency components of which are essentially displaced by a factor of N at higher frequencies relative to the ripple voltage generated by an individual switching power supply 10ᵢ. Given a switching frequency of a single switching power supply 10ᵢ of, for example, 200 kHz and N=10 switching power supplies 10ᵢ, the typical frequency of the ripple voltage is thus on the order of approximately 2 MHz. The ripple voltage generated in total by the amplitude modulator 5 is thus clearly spectrally separated from the typical frequencies of the amplitude modulation.

In the event that it is required or reasonable for the concrete MR application, one or more frequency filters (not shown) are additionally provided to suppress the ripple voltage in the framework of the MR transmitter 1, which frequency filters are selectively interconnected in the supply voltage path between the amplitude modulation 5 and the transmission output stage 2 and/or are downstream on the output side from the transmission stage 2.

Although modifications and changes may be suggested by those skilled in the art, it is the intention of the inventors to embody within the patent warranted hereon all changes and modifications as reasonably and properly come within the scope of their contribution to the art.

I claim as my invention:

1. Device to generate a modulated electrical radio-frequency signal for a magnetic resonance application, comprising a phase modulator that generates a phase-modulated radio-frequency base signal, an amplitude modulator that generates an amplitude-modulated supply voltage, and a non-linear transmission output stage that, to supply the radio-frequency base signal, is connected via a signal input with the phase modulator and, to feed in the supply voltage, is connected via a supply voltage input with the amplitude modulator, said amplitude modulator comprising at least two switching power supplies connected in parallel and clocked phase-offset relative to one another.

2. Device according to claim 1, wherein the switching power supplies are phase-offset by a respective switching phase difference of 2π/N, wherein N is the number of switching power supplies.

3. Device according to claim 1, wherein the switching power supplies are buck converters.

4. Device according to claim 1, wherein a driver amplifier is interconnected between the phase modulator and the transmission output stage.
